(19) United States
(12) Patent Application Publication
(10) Pub. No.: US 2012/0289141 A1
(43) Pub. Date: Nov. 15, 2012

(54) HEAT DISSIPATION DEVICE AND HEAT DISSIPATION SYSTEM HAVING SAME

(75) Inventors: HUNG-YI WU, Tu-Cheng (TW); LEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/177,560

(22) Filed: Jul. 7, 2011

(30) Foreign Application Priority Data
May 12, 2011 (CN) 201110122152.5

(51) Int. Cl. H05K 5/02

(52) U.S. Cl. 454/184

(57) ABSTRACT

A heat dissipation device includes a support and an auxiliary blower to increase the efficiency of the heat dissipation from a computer. The location of the auxiliary blower is variable, to achieve the most effective heat dissipation. The support includes a support plate and a connection plate perpendicularly extending from an edge of the support plate. The connection plate defines an exhaust. The blower includes a housing. The housing includes a first surface, an opposing second surface, an inlet and an outlet communicating with the inlet. The blower is mounted on the support plate. The second surface contacts with the support plate. The inlet is positioned on the first surface. The outlet is aligned with the exhaust.

### BACKGROUND

1. Technical Field

The present disclosure relates to heat dissipation technologies, and particularly, to a heat dissipation device and a dissipation system having the heat dissipation device.

2. Description of Related Art

Electronic devices, such as computers, require dissipation of heat generated by electronic components, such as a central processing unit (CPU), a display card, or an expansion card, such as a video card or a graphics accelerator card, to prevent damage to the components from overheating. Thus, heat dissipation devices, such as fans are used to dissipate the heat generated by the electronic components. However, the large size of an expansion card makes the removal of heat from it a complex matter, and this is a difficult task for a simple fan, which does not perform the task efficiently.

Therefore, it is desirable to provide a heat dissipation device and a heat dissipation system having the same, which can overcome or at least alleviate the limitations described.

### BRIEF DESCRIPTION OF THE DRAWINGS

FIG. 1 is a schematic, isometric view of a heat dissipation system including a heat dissipation device, according to an exemplary embodiment.

FIG. 2 is an exploded view of the heat dissipation system of FIG. 1.

FIG. 3 is an exploded view of the heat dissipation device of FIG. 2.

### DETAILED DESCRIPTION

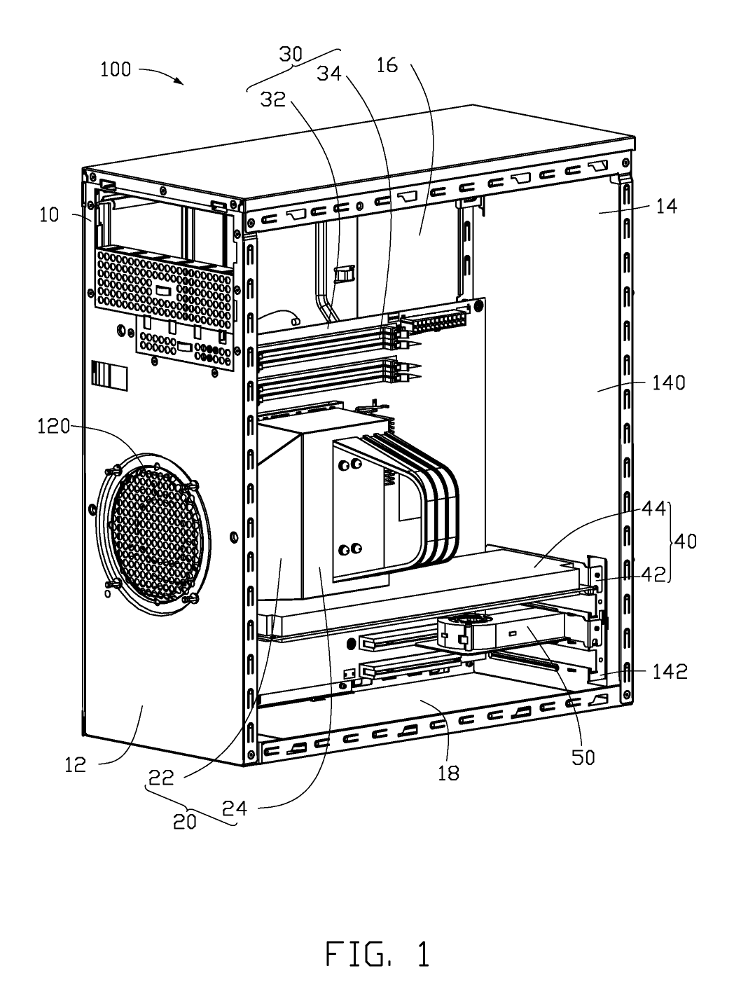

Referring to FIG. 1, a heat dissipation system 100, according to an exemplary embodiment, includes a computer enclosure 10, a fan assembly 20, a first heat source assembly 30, a second heat source assembly 40, and a heat dissipation device 50. The fan assembly 20, the first heat source assembly 30, the second heat source assembly 40, and the heat dissipation device 50 are positioned inside the computer enclosure 10 in the illustrated embodiment.

The computer enclosure 10 is a cuboid. The computer enclosure 10 includes a back panel 12, a front panel 14, a side panel 16, and a rectangular bottom panel 18. The back panel 12, the front panel 14, and the side panel 16 perpendicularly extend from three edges of the bottom panel 18. The front panel 14 is substantially parallel to the back panel 12. The side panel 16 is perpendicularly connected between the back panel 12 and the front panel 14. The back panel 12 defines a vent 120. The front panel 14 includes a panel body 140 and a flange 142 perpendicularly extending from the panel body 140.

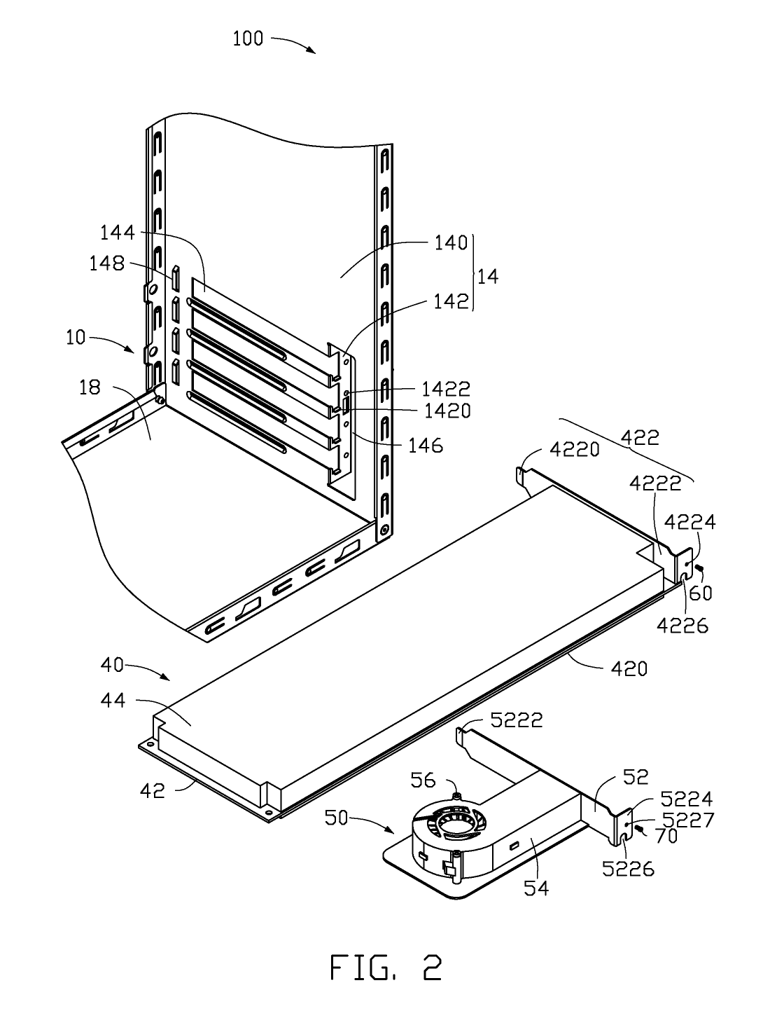

Referring to FIG. 2 together with FIG. 1, the panel body 140 includes four elongated slots 144, an elongated opening 146, and four ribs 148. The slots 144 are rectangular and parallel to each other. The longitudinal centerline of the slots 144 is perpendicular to the longitudinal centerline of the bottom panel 18. The longitudinal centerline of the bottom panel 18 is from the back panel 12 to the front panel 14. The opening 146 is vertically rectangular and one end of each of the four slots 144 extends into the opening 146. The four ribs 148 are in line with the four slots 144 (although perpendicular to them) and project towards the interior of the computer enclosure 10. The four ribs 148 and the opening 146 are positioned at opposite ends of the slots 144.

The flange 142 effectively forms a frame around the end of each of the slots 144 in the opening 146. The flange 142 and the bottom panel 18 are positioned at opposite sides of the panel body 140. Four engagement portions 1420 and four fixing threaded holes 1422 are formed on the flange 142. In particular, the four engagements portions 1420 and the four fixing threaded holes 1422 serve the four slots 144. In other words, there is a one-to-one correspondence between the slots 144, the ribs 148, the engagement portions 1420, and the fixing threaded holes 1422.

The fan assembly 20 includes a fan 22 and an air guiding device 24. The fan 22 is mounted on the internal side of the back panel 12 and aligned with the vent 120. The air guiding device 24 is mounted on the back panel 12 and encloses the fan 22. The air guiding device 24 is configured for introducing air flow from the fan 22 to the first heat source assembly 30 and the second heat source assembly 40.

The first heat source assembly 30 includes a motherboard 32 and electronic components 34. The motherboard 32 is attached to the side panel 16. The electronic components 34 are mounted on the motherboard 32 and electrically connected to the motherboard 32.

The second heat source assembly 40 includes a bracket 42 and an expansion card 44. The bracket 42 includes a horizontal plate 420 and a vertical plate 422. The horizontal plate 420 is substantially parallel to the bottom panel 18. The vertical plate 422 perpendicularly extends from one end of the horizontal plate 420. The vertical plate 422 includes a first end 4220 and an L-shaped second end 4222. The first end 4220 and the second end 4222 are positioned at opposite sides of the vertical plate 422 along the lengthwise direction of the vertical plate 422. The second end 4222 defines a connecting hole 4224 and a cutout 4226 independent of the connecting hole 4224. The first end 4220 engages with a corresponding rib 148. The second end 4222 extends through the opening 146. The engagement portion 1420 engages with the cutout 4226. A screw or bolt (bolt 60) extends through the connecting hole 4224 and engages in the corresponding fixing threaded hole 1422 so that the bracket 42 is mounted on the front panel 14 and the vertical plate 422 covers the corresponding slot 144. The expansion card 44 is mounted on the horizontal plate 420 and is electrically connected to the motherboard 32.

The heat dissipation device 50 includes a support 52, a blower 54, and two fasteners or bolts (bolts 56).

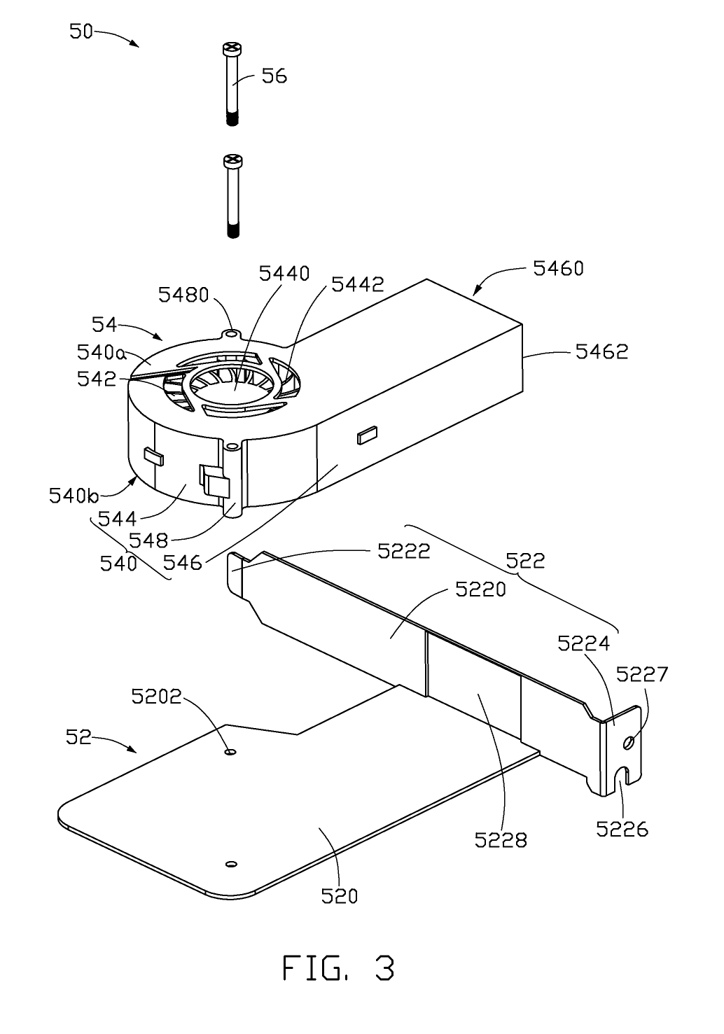

Referring to FIGS. 1-3, the support 52 includes a support plate 520 and a connection plate 522. The support plate 520 is substantially parallel to the bottom plate 18. The support plate 520 defines two first threaded holes 5202. The connection plate 522 perpendicularly extends from an end of the support plate 520. The connection plate 522 includes a connection body 5220, a first connection portion 5222, and a second connection portion 5224. The connection body 5220 defines an exhaust opening 5228. The first connection portion 5222 extends from one end of the connection body 5220, the second connection portion 5224 perpendicularly extends from the other end of the connection body 5220. The second connection portion 5224 and the support plate 520 are positioned at opposite sides of the connection body 5220. The second connection portion 5224 defines an engagement hole 5226 and a second threaded hole 5227.

The blower 54 includes a housing 540 and a fan unit 542. The housing 540 includes a fixing portion 544, an air guiding portion 546, and two protruding portions 548. Without the air guiding portion 546, the fixing portion 544 is substantially cylindrical and defines a receiving cavity 5440. The air guiding portion 546 is substantially rectangular in section and defines a passage 5460 for guiding air. One end of the air guiding portion 546 extends from the circumferential wall of the fixing portion 544, and the other end of the air guiding portion 546 defines an outlet 5462. The protruding portions 548 extend from the circumferential wall of the fixing portion 544 and are diametrically opposed. Each protruding portion 548 defines a through hole 5480, the through holes 5480 correspond to the two bolts 56 and the two first threaded holes 5202.

The housing 540 includes a first surface 540a and a second surface 540b opposite to the first surface 540a. The first surface 540a is parallel to the expansion card 44 and defines an inlet 5442 in the fixing portion 544. The second surface 540b is attached on the support plate 520. The fan unit 542 includes a plurality of blades rotatable about a rotation axis perpendicular to the support plate 520. The fan unit 542 is received in the receiving cavity 5440 and is aligned with the inlet 5442. The fan unit 542 is configured for blowing air to the outlet 5462 through the passage 5460.

When the heat dissipation device 50 is assembled, the bolts 56 extend the respective through holes 5480 and engage in the respective first threaded holes 5202 so that the blower 54 is mounted on the support plate 520 and the outlet 5462 is aligned with the exhaust opening 5228. In other embodiments, the blower 54 may be mounted on the support plate 520 with adhesive.

In this embodiment, the heat dissipation device 50 is positioned between the bottom panel 18 and the second heat source assembly 40. In other embodiments, the second heat source assembly 40 may be positioned between the bottom panel 18 and the heat dissipation device 50.

When the heat dissipation device 50 is mounted on the computer enclosure 10, the first connection portion 5222 engages with a corresponding rib 148, and the second connection portion 5224 extends through the opening 146. The engagement hole 5226 engages with the corresponding engagement portion 1420. A screw or bolt (bolt 70) extends through the second threaded hole 5227 and engages in the corresponding fixing threaded hole 1422 so that the support 52 is mounted on the front panel 14 and the connection plate 522 covers the corresponding slot 144.

When the heat dissipation system 100 is working, the fan 22 blows air onto the first heat source assembly 30 and the second heat source assembly 40. The air carries away the heat generated from the first heat source assembly 30 and the second heat source assembly 40. The air is taken into the inlet 5442 and blown to the outlet 5462 by the fan unit 542, thereby removing hot air from inside the computer enclosure 10. The heat dissipation efficiency of the heat dissipation system 100 is significantly greater than other heat dissipation systems.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of the shape, size, and arrangement of parts within the principles of the disclosure to the full extent indicated by the broad general meaning of the terms in which the appended claims are expressed.

What is claimed is:

1. A heat dissipation device for mounting on a computer enclosure, the computer enclosure including a panel defining a slot, the heat dissipation device comprising:
a support comprising a support plate and a connection plate perpendicularly extending from a longitudinal edge of the support plate, the connection plate configured for mounting on the panel and covering the slot, the connection plate defining an exhaust opening, and
a blower comprising a housing, the housing having a first surface, an opposing second surface, an inlet and an outlet communicating with the inlet, the blower mounted on the support plate with the second surface attached on the support plate, the inlet defined in the first surface, the outlet aligned with the exhaust opening.

2. The heat dissipation device as claimed in claim 1, wherein the blower is mounted on the support plate with adhesive.

3. The heat dissipation device as claimed in claim 1, wherein the blower further comprises a fan unit including a plurality of blades rotatable about a rotation axis perpendicular to the support plate.

4. The heat dissipation device as claimed in claim 3, wherein the inlet is aligned with the fan unit.

5. The heat dissipation device as claimed in claim 4, further comprising two bolts, the bolts extending through the housing and engaged with the support plate.

6. The heat dissipation device as claimed in claim 1, wherein the connection plate comprises a connection body, a first connection portion, and a second connection portion, the exhaust opening is defined in the connection body, the first connection portion extends from one end of the connection body, the second connection portion perpendicularly extends from the other end of the connection body, the second connection portion and the support plate are positioned opposite sides of the connection body.

7. The heat dissipation device as claimed in claim 6, wherein the second connection plate has a threaded hole and an engagement hole.

8. A heat dissipation system comprising:
a computer enclosure having a back panel, a front panel parallel to the back panel, a side panel perpendicularly connecting the back panel and the front panel, the front panel defining a plurality of slots;
a fan assembly mounted on the back panel;
a first heat source assembly mounted on the side panel;
a second heat source assembly perpendicularly mounted on the front panel; and
a heat dissipation device comprising:
a support comprising a support plate and a connection plate perpendicularly extending from an edge of the support plate, the connection plate mounted on the front panel and arranged at one of the slots, the connection plate defining an exhaust opening, and
a blower comprising a housing, the housing having a first surface, an opposing second surface, an inlet and an outlet communicating with the inlet, the blower mounted on the support plate with the second surface attached on the support plate, the inlet defined in the first surface and facing the second heat source assembly, the outlet aligned with the exhaust opening.

9. The heat dissipation system as claimed in claim 8, wherein the heat dissipation device and the fan assembly are positioned at opposite sides of the second heat source assembly.

10. The heat dissipation system as claimed in claim 9, wherein the computer enclosure further comprises a bottom panel, the back panel, the front panel, and the side panel perpendicularly extend from three edges of the bottom panel, the second heat source assembly and the support plate are parallel to the bottom panel, the heat dissipation device are positioned between the second heat source assembly and the bottom panel.

11. The heat dissipation system as claimed in claim 8, wherein the blower is mounted on the support plate with adhesive.

12. The heat dissipation system as claimed in claim 8, wherein the blower further comprises a fan unit including a plurality of blades rotatable about a rotation axis perpendicular to the support plate.

13. The heat dissipation system as claimed in claim 12, wherein the inlet is aligned with the fan unit.

14. The heat dissipation system as claimed in claim 13, further comprising two bolts, wherein the bolts extend through the respective through the housing and engaged with the support plate.

15. The heat dissipation system as claimed in claim 8, wherein the connection plate comprises a connection body, a first connection portion, and a second connection portion, the exhaust opening is defined in the connection body, the first connection portion extends from one end of the connection body along the lengthwise direction of the connection body, the second connection portion perpendicularly extends from the other end of the connection body, the second connection portion and the support plate are positioned opposite sides of the connection body.

16. The heat dissipation system as claimed in claim 15, wherein the second connection plate has a threaded hole and an engagement hole.
